(19) United States
(12) Patent Application Publication
(10) Pub. No.: US 2008/0283903 A1
(43) Pub. Date: Nov. 20, 2008

(54) Transistor With Quantum Dots in Its Tunnelling Layer

(75) Inventors: Stefan Peter Grabowski, Aachen (DE); Cornelis Reinder Ronda, Aachen (DE)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: KONINKLIJKE PHILIPS ELECTRONICS N.V., Eindhoven (NL)

(21) Appl. No.: 10/585,063

(22) PCT Filed: Dec. 22, 2004
(86) PCT No.: PCT/IB2004/052905

§ 371 Date: Aug. 12, 2008

(30) Foreign Application Priority Data
Jan. 6, 2004 (EP) 04100011.8

(51) Int. Cl. H01L 29/792; H01L 21/336

(52) U.S. Cl. 257/325; 438/287; 257/E21.423; 257/E29.309

(57) ABSTRACT

According to an example embodiment there is a semiconductor component, which is arranged in a semiconductor body, with at least one source zone and with at least one drain zone which in each case is a first conductivity type, with at least one body zone of a second conductivity type arranged in each case between source zone and drain zone, and with at least one gate electrode insulated with an insulating layer relative to the semiconductor body. The insulating layer is a consolidated, preferably sintered, layer containing quantum dots.

The invention relates to a semiconductor component, which is arranged in a semiconductor body, with at least one source zone and with at least one drain zone of in each case a first conductivity type, with at least one body zone of a second conductivity type arranged in each case between source zone and drain zone, and with at least one gate electrode insulated relative to the semiconductor body by means of an insulating layer. The invention also relates to a method of producing a semiconductor component.

Components with transistor function are known in a wide range of embodiments, one of these embodiments being of the field effect transistor (FET) type. In the case of a field effect transistor, the charge carrier density in an electrical channel, which is placed in contact with the source zone and the drain zone, is modified by the application of a voltage to a control electrode (gate electrode). The control electrode may be isolated from the channel either by a blocking PN-junction (JFET) or by an insulating layer (generally SiO₂ or a metal oxide) (MOSFET). In the case of a MOSFET, a conducting channel is generated by induction under the gate electrode as the gate voltage increases. The type of the voltage, i.e. positive or negative voltage, depends on the doping type of the FET.

There is a lot of interest in the production of so-called single electron transistors, which inter alia have great potential for use in non-volatile memories. A MOSFET with quantum dots in the gate oxide is such a single electron transistor. When a voltage is applied to the gate electrode, electrons tunnel through the gate oxide to the quantum dots and are taken up thereby. The number of electrons which may be taken up by a quantum dot is limited by the negative charging of the quantum dot and the resultant Coulomb repulsion between a negatively charged quantum dot and a negatively charged electron.

The retention time, i.e. the time in which the charge is stored in the quantum dots in the gate oxide, is very long in such a transistor, since the electrons have to overcome a high energy barrier when tunneling away. This makes the use of these single transistors in non-volatile memories of particular interest. The energy barrier may be lowered by applying a voltage to the gate electrode.

U.S. Pat. No. 6,586,785 describes a transistor in which the floating gate of a transistor contains a layer of semiconductor nanoparticles, which are surrounded by a dielectric shell. The floating gate is arranged between two oxide layers, wherein one thereof is the tunnel oxide. The nanoparticles are produced and deposited using vacuum technology.

A disadvantage of this transistor is that production using vacuum technology is very complex and expensive. Production of the tunnel oxide layer frequently presents further difficulties. The tunnel oxide layer must not be too thin and thus conductive, since otherwise short circuits occur. On the other hand, it must not be too thick or the electrons would not be able to tunnel through it.

It is therefore an object of the invention to provide an improved semiconductor component with insulating layer, which is simple and economic to produce.

This object is achieved by a semiconductor component, which is arranged in a semiconductor body, with at least one source zone and with at least one drain zone of in each case a first conductivity type, with at least one body zone of a second conductivity type arranged in each case between source zone and drain zone, and with at least one gate electrode insulated relative to the semiconductor body by means of an insulating layer, the insulating layer being a consolidated layer containing quantum dots.

The semiconductor component according to the invention has the advantage that a consolidated insulating layer is used which does not contain any individually arranged quantum dots, the quantum dots instead being arranged in a continuous layer, which is therefore more robust.

Also, no tunnel oxide layer needs to be applied in the case of the semiconductor component according to the invention. This simplifies the process of producing the semiconductor component and reduces the number of contact problems, which can arise at the layer interfaces when the semiconductor component is in operation, since fewer layers are present in the semiconductor component.

A further advantage of the semiconductor component according to the invention is that the quantum dots may be produced by wet-chemical processes, thus reducing the cost of production of the semiconductor component.

The invention additionally relates to a method of producing a semiconductor component, which is arranged in a semiconductor body, with at least one source zone and with at least one drain zone of in each case a first conductivity type, with at least one body zone of a second conductivity type arranged in each case between source zone and drain zone, and with at least one gate electrode insulated relative to the semiconductor body by means of a consolidated insulating layer containing quantum dots, in which method the consolidated insulating layer is produced by applying a suspension containing quantum dots to the semiconductor body and consolidating it.

When producing the insulating layer, the melting point depression of nanocrystalline materials is advantageously exploited. By exploiting this effect, the insulating layer may be consolidated at low temperatures T, generally at T<300° C.

Further advantageous developments are revealed by the respective dependent claims.

The invention will be further described with reference to examples of embodiments shown in the drawings to which, however, the invention is not restricted. In the Figs:

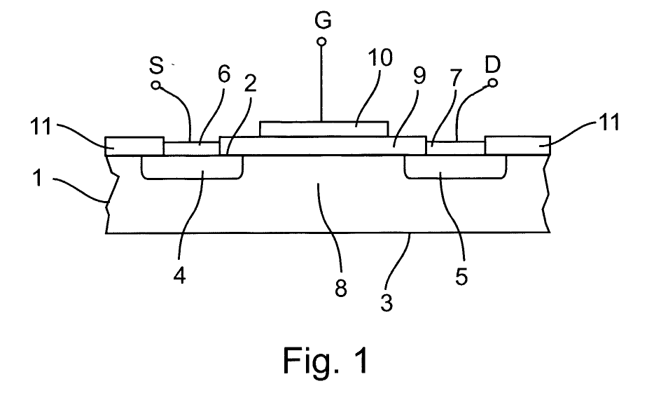

FIG. 1 shows in cross section the structure of a MOS field effect transistor.

FIG. 1 is a schematic view of the structure of a MOSFET. A semiconductor body 1, for example of silicon, GaAs, SiC, GaN or InP, comprises a first surface 2 (wafer front) and a second surface 3 (wafer back). A strongly n-doped source zone 4 and a strongly n-doped drain zone 5 spaced therefrom are introduced into the first surface 2. In this embodiment of a MOSFET, the first conductivity type is accordingly n-conductive, the second conductivity type p-conductive, and an n-channel MOSFET is obtained. In principle, the n- and p-doping may be reversed, such that a p-channel MOSFET is obtained. Boron may be used for example as the doping atom for the p-conductive regions and phosphorus, arsenic or antimony may be used for example as the doping atoms for n-conductive regions. The source zone 4 is contacted in electrically conductive manner via a source metallization 6 (source electrode) and the drain zone 5 via a drain metallization 7 (drain electrode). A p-conductive body zone 8 is arranged between source zone 4 and drain zone 5. In the area of the regions of the body zone 8 located at the first surface 2 there is arranged a gate electrode 10 (control electrode) insulated from the semiconductor body 1 via an insulating layer 9. The gate electrode 10, the source electrode 6 and the drain electrode 7 are connected respectively to the gate terminal G, source terminal S and drain terminal D and are outwardly insulated, at a distance from one another at the first surface 2, by means of a passivation layer not shown in FIG. 1, for example a field oxide. Insulating regions 11 are also located at the marginal areas of the semiconductor component. The gate electrode 10, the source electrode 6 and the drain electrode 7 may contain as materials for example Al, Au—Sb, Ni—Ge, Au—Ni—Ge, Ni—Ag—Ge, Ni—Pd—Ge, Ni—Pt—Ge, Ni—In—Ge, Ti, Al—Ti, Al—Ti—Al, Ni, Ti—Au or Pd—Au. The choice of material in each individual case depends inter alia on the semiconductor material used and the type of doping.

The consolidated insulating layer 9 contains quantum dots, which are embedded in a dielectric matrix. The quantum dots contain for example so-called composite semiconductors, i.e. semiconductors composed of various elements from the main groups of the Periodic Table. The semiconductor material is for example a group IV material, a group III/V material, a group II/VI material, a group I/VII material or a combination of one or more of these semiconductor materials. Preferably the quantum dots contain Si or group II/V materials such as for example CdSe, CdS, CdTe, ZnS, HgS, ZnTe, ZnSe, ZnO or group III/V materials such as for example InP, InAs, InN, GaAs, GaN, GaP, GaSb, AlAs or AlP. A quantum dot may also contain TiO₂, PbS or any other desired material.

Alternatively, the quantum dots may be so constructed that a quantum dot contains a core of a semiconductor material, which is surrounded by a large-band-gap dielectric shell. The material of the dielectric shell is a dielectric material such as for example SiO₂, Al₂O₃ or Y₂O₃. These materials exhibit a high band gap and therefore have good insulating properties. Such quantum dots are also known as “core/shell quantum dots”. Preferred quantum dots with a core/shell structure are for example TiO₂/SiO₂ or ZnS/SiO₂.

The diameter of the quantum dots or the diameter of the core in core/shell quantum dots depends on the material depends on the material used and amounts preferably to between 1 and 10 nm. It may in particular be preferred for the diameter of the quantum dots to be between 1 and 5 nm. The layer thickness of the dielectric shell also depends on the material used. The layer thickness must not be too great, since otherwise the electrons can no longer tunnel through the dielectric matrix to the quantum dots in the finished, consolidated insulating layer 9. The layer thickness must not be too small either, since otherwise the dielectric matrix may be insufficiently insulated, so resulting in short circuits. The layer thickness of the dielectric shells is preferably in the range of 2.5 nm.

In this context, consolidation describes the physical process of bringing together particles, namely the quantum dots, to form a continuous insulating layer 9. This may take place for example by means of heat, pressure, exposure to light, chemical reaction or a combination of these means. It is particularly preferable for the consolidation process to be effected by means of heat. This process may also be designated sintering of the insulating layer 9.

The quantum dots are produced as a rule by means of colloidal chemical synthesis. In this process, the reaction partners, generally a metal-containing compound and a non-metal-containing compound, are mixed in an organic solvent or in water and caused to react at elevated temperatures.

To produce quantum dots containing a core and a dielectric shell, first of all the core is produced as described above. Then the solution is cooled and one or more precursors of the dielectric shell are added to the solution.

In the case of dielectric shells of SiO₂, first of all the cores are produced and dispersed in an alcoholic solution. After adding tetraethylorthosilicate (TEOS) and increasing the pH value, an SiO₂ precursor is deposited on the cores. By heating the solution to temperatures of around 400° C., a complete shell of SiO₂ is obtained. In the case of dielectric shells of Y₂O₃, first of all the cores are produced as described above. Then an aqueous solution of Y(NO₃)₃ is mixed with (NH₂)₂CO and added to the solution containing the cores. On heating this mixture to 80° C., Y(OH)CO₃ is slowly deposited on the cores, which is then converted into Y₂O₃ at temperatures of around 600° C.

During the precipitation reaction, complexing ligands are added, which bind to the surface of a quantum dot. To improve size distribution, size fractionation may then be performed.

The complexing ligands preferably comprise organic ligands, which vaporize without leaving a residue during the consolidation process, especially during sintering. Pyridine is preferably used as the complexing ligand. Alternatively, first of all other complexing ligands such as for example hexadecylamine (HDA), trioctylphosphine oxide (TOPO) and/or trioctylphosphine (TOP) may be used during synthesis of the quantum dots. Before production of the consolidated insulating layer 9, these are replaced by pyridine through repeated washing with pyridine.

Depending on the type of quantum dots, two different variants are used to produce a consolidated insulating layer 9:

To produce a consolidated insulating layer 9 on the basis of quantum dots with dielectric shells, the suspension containing the stabilized quantum dots is applied to the semiconductor body 1. This may be performed for example by means of repeated dipping of the semiconductor body 1 into the suspension, spin coating, electrophoresis or sedimentation.

The insulating layer 9 is then consolidated at temperatures of up to 350° C., preferably up to 300° C., in an inert atmosphere. The consolidation temperatures may be lowered if overpressure is applied during the consolidation process.

During the consolidation process, the shells melt before the cores and the material of the shells also spreads between the cores of the quantum dots. After cooling, a continuous, consolidated insulating layer 9 is obtained, in which the quantum dots are embedded in the dielectric matrix. With this variant the dielectric matrix is formed from the dielectric shells of the quantum dots.

Alternatively, such a consolidated insulating layer 9 may be obtained in which particles of a dielectric material are added to the suspension containing the stabilized quantum dots, wherein the particle diameter of the dielectric material is smaller than the particle diameter of the whole quantum dots (including shell). The insulating layer 9 is then applied to the semiconductor body 1 and consolidated, as described above. During the consolidation process, the particles of the dielectric material melt before the quantum dots as a result of the melting point depression of nanocrystalline materials and the dielectric material spreads homogeneously between the quantum dots. A consolidated insulating layer 9 is obtained, which contains a continuous film of the dielectric material, in which the quantum dots are distributed. In these variants, quantum dots may be used with or without an insulating shell. The quantity of dielectric material is so selected that it is possible for electrons to tunnel to the quantum dots in the consolidated insulating layer 9. The dielectric material is preferably SiO₂, Al₂O₃ or Y₂O₃. It is additionally preferable, where quantum dots with dielectric shell are used, for the material of the dielectric shell to be identical to the material of the dielectric particles.

On operation of the semiconductor component, electrons tunnel from the body zone 8 into the consolidated insulating layer 9 when a corresponding voltage is applied to the gate electrode 10 and are stored by the quantum dots. The dielectric matrix, formed from the dielectric shell material and/or the dielectric particles, functions between a quantum dot and the body zone 8 as tunnel oxide. The charges (=electrons) are only taken up by the quantum dots located at the edge facing the body zone 8. The region of the consolidated insulating layer 9 located thereabove serves as insulation. Thus, in contrast to the semiconductor component according to the prior art, in the semiconductor component according to the invention only a single layer, namely the consolidated insulating layer 9, is required and no layer structure consisting of tunnel oxide, quantum dots and insulating oxide is needed. The semiconductor component may additionally still comprise an oxide layer between the gate electrode 10 and the consolidated insulating layer 9, but even this embodiment is still advantageous relative to the prior art, since the tunnel oxide layer, which is sometimes difficult to produce, is eliminated.

The semiconductor component itself is produced using known methods.

### EXAMPLE OF EMBODIMENT 1

To produce a semiconductor component according to the invention, first of all the n-conductive source zone 4 and the n-conductive drain zone 5 were produced by ion implantation of phosphorus into the semiconductor body 1 of boron-doped silicon. Then the source electrode 6 and the drain electrode 7 of Al doped with 0.5 wt. % Cu were applied using a lithographic method. A suspension containing TiO₂/SiO₂ quantum dots was applied between the two electrodes 4, 5 by spin coating and consolidated at temperatures of up to 300° C. in an inert atmosphere. The consolidated insulating layer 9 contained TiO₂ quantum dots with a diameter of 5 nm embedded in a matrix of SiO₂. After cooling to room temperature, the gate electrode 10 of Al was applied to the insulating layer 9.

1. A semiconductor component which is arranged in a semiconductor body, with at least one source zone and with at least one drain zone of in each case a first conductivity type, with at least one body zone of a second conductivity type arranged in each case between source zone and drain zone, and with at least one gate electrode insulated from the semiconductor body by means of an insulating layer, the insulating layer being a consolidated layer containing quantum dots.

2. A semiconductor component as claimed in claim 1, characterized in that the consolidated insulating layer contains quantum dots embedded in a matrix of a dielectric material.

3. A semiconductor component as claimed in claim 1, characterized in that the quantum dots contain a semiconductor material.

4. A semiconductor component as claimed in claim 1, characterized in that the consolidated insulating layer 9 is a sintered layer.

5. A method of manufacturing a semiconductor component which is arranged in a semiconductor body, with at least one source zone and with at least one drain zone of in each case a first conductivity type, with at least one body zone of a second conductivity type arranged in each case between source zone and drain zone, and with at least one gate electrode insulated from the semiconductor body by means of a consolidated insulating layer containing quantum dots, in which method the consolidated insulating layer is produced by applying a suspension containing quantum dots to the semiconductor body and consolidating it.

6. A method as claimed in claim 5, characterized in that consolidation of the insulating layer is effected by means of sintering.

7. A method as claimed in claim 5, characterized in that the suspension additionally contains particles of a dielectric material, wherein the diameter of the particles of the dielectric material is smaller than the diameter of the quantum dots.
